(19) United States
(12) Patent Application Publication
(10) Pub. No.: US 2026/0173796 A1
(43) Pub. Date: Jun. 18, 2026

(54) MODULE CIRCUIT AND OPERATION METHOD THEREOF

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Honghua ZHU, Shanghai City (CN); Zhirong DAI, Shanghai City (CN); Yifei ZHANG, Shanghai City (CN); Guo Ping HE, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/003,236

(22) Filed: Dec. 27, 2024

(30) Foreign Application Priority Data
Dec. 12, 2024 (CN) 202411841227.9

(51) Int. Cl. H01L 21/67

(52) U.S. Cl. CPC H10P 72/0602

(57) ABSTRACT

The system includes a process architecture; and a module circuit coupled to the process architecture through a plurality of ports and configured to operate at least one of: generating, based on at least one detection pattern, at least one first control signal to the process architecture to control at least one operation process; comparing sensing data from the process architecture with at least one threshold data to generate a comparison result; and generating, based on the comparison result, at least one second control signal to the process architecture, wherein the process architecture is configured to perform at least one first process in response to the at least one second control signal.

### CROSS REFERENCE

The present application claims priority to China Application Serial Number 202411841227.9 filed on Dec. 12, 2024, which is herein incorporated by reference in its entirety.

### BACKGROUND

Manufacturing industry faces challenges in machine modification projects due to the need for programming and circuit design skills. The diverse sensors and lack of internet connectivity in machines complicate real-time monitoring and upgrades.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a manufacturing system, in accordance with various embodiments of the present disclosure.

FIG. 2 is a schematic diagram of a cluster-type architecture, in accordance with various embodiments of the present disclosure.

FIG. 3 is a schematic diagram of the module circuit corresponding to FIG. 2, in accordance with various embodiments of the present disclosure.

FIG. 4 is a flowchart diagram of a method for operating a manufacturing system, in accordance with some embodiments of the present disclosure.

FIGS. 5A-5D show schematic diagrams of screen snaps corresponding to the touch display during operations, in accordance with various embodiments of the present disclosure.

FIG. 6 shows a schematic diagram of a screen snap corresponding to the touch display during operations, in accordance with various embodiments of the present disclosure.

FIG. 7 shows a schematic diagram of a screen snap corresponding to the touch display during operations, in accordance with various embodiments of the present disclosure.

FIG. 8 shows a schematic diagram of a screen snap corresponding to the touch display during operations, in accordance with various embodiments of the present disclosure.

FIGS. 9A-9D show schematic diagrams of components in a power circuit, in accordance with various embodiments of the present disclosure.

FIGS. 10A-10C show schematic diagrams of components in a main control circuit, in accordance with various embodiments of the present disclosure.

FIG. 11 is a schematic diagram of a coupling capacitor circuit, in accordance with various embodiments of the present disclosure.

FIGS. 12A-12B show schematic diagrams of components in an internet communication port, in accordance with various embodiments of the present disclosure.

FIGS. 13A-13B show schematic diagrams of a communication port and a communication setting circuit coupled thereto, in accordance with various embodiments of the present disclosure.

FIG. 14 is a schematic diagram of communication ports and a converter coupled thereto, in accordance with various embodiments of the present disclosure.

FIG. 15 is a schematic diagram of a touch display port, in accordance with various embodiments of the present disclosure.

FIG. 16 is a schematic diagram of a buzzer control circuit, in accordance with various embodiments of the present disclosure.

FIG. 17 is a schematic diagram of a memory circuit, in accordance with various embodiments of the present disclosure.

FIG. 18 is a schematic diagram of an indicator, in accordance with various embodiments of the present disclosure.

FIGS. 19A-19D show schematic diagrams of components in an analog input, in accordance with various embodiments of the present disclosure.

FIGS. 20A-20B show schematic diagrams of components in a communication port, in accordance with various embodiments of the present disclosure.

FIGS. 21A-21B show schematic diagrams of components in a relay control circuit, in accordance with various embodiments of the present disclosure.

FIGS. 22A-22B show schematic diagrams of components in pulse control circuits, in accordance with various embodiments of the present disclosure.

FIG. 23 is a schematic diagram of a program port, in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

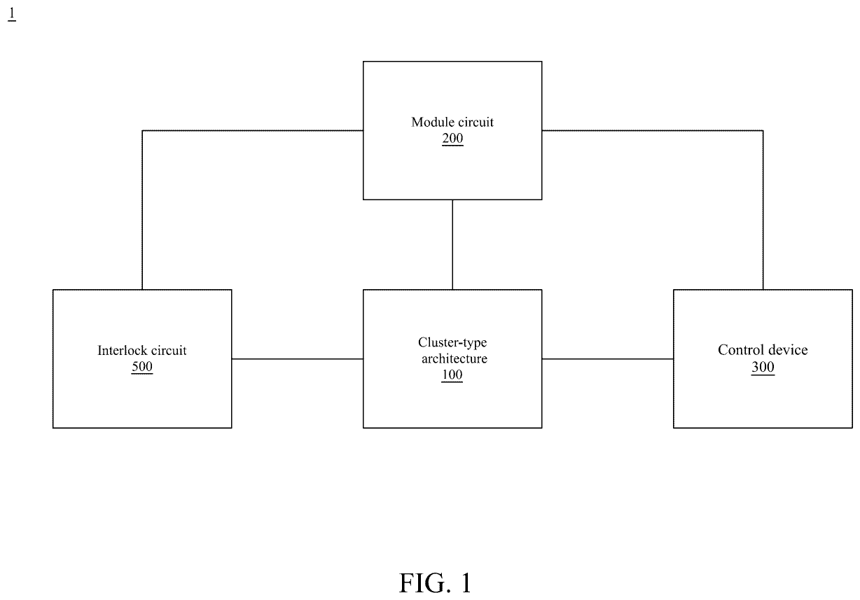

Reference is now made to FIG. 1. FIG. 1 is a schematic diagram of a manufacturing system 1, in accordance with various embodiments of the present disclosure. For illustration, the manufacturing system 1 includes a cluster-type architecture 100, a module circuit 200, an interlock circuit 500 coupled between the module circuit 200 and the cluster-type architecture 100, and a control device 300. In some embodiments, the cluster-type architecture 100 is a process architecture for manufacturing semiconductor devices in response to control signals/orders from the module circuit 200 and the control device 300.

In some embodiments, the cluster-type architecture 100 and the module circuit 200 are coupled to the control device 300 and communicate with the control device 300 through the network interface including wireless network interfaces, such as BLUETOOTH, WIFI, WIMAX, GPRS, or WCDMA, and wired network interfaces such as ETHERNET, USB, or IEEE-1364 in manufacturing processes performed to multiple wafers in lots. In some embodiments, the cluster-type architecture 100 is controlled in response to commands received from the module circuit 200. The module circuit 200 is electrically coupled to the cluster-type architecture 100 and configured to fetch signals indicating manufacturing parameters of the cluster-type architecture 100 in the manufacturing processes and to control operations of the cluster-type architecture 100 through control signals generated in response to manufacturing parameters.

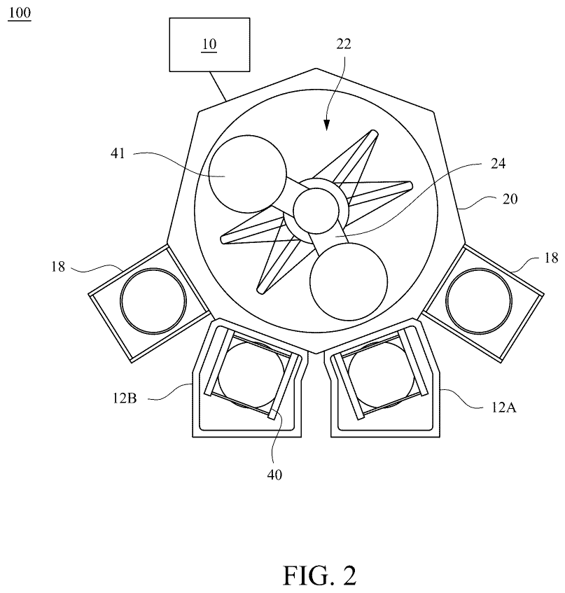

Reference is now made to FIG. 2. FIG. 2 is a schematic diagram of the cluster-type architecture 100 corresponding to FIG. 1, in accordance with various embodiments of the present disclosure.

In some embodiments, the cluster-type architecture 100 facilitates integration of the multiple process steps (e.g., the chemical vapor deposition, etching and other processes used in the formation of integrated circuits on the wafers) and improve wafer manufacturing throughput. The cluster-type architecture 100 includes a controller 10 to control the components therein in response to command, associated with processes being performed to the wafers, from the module circuit 200 and/or the control device 300. For example, the controller 10 in the cluster-type architecture 100 is a general-purpose computing device including a hardware processor and a non-transitory, computer-readable storage medium. Storage medium, amongst other things, is encoded with, i.e., stores, computer program code (instructions), i.e., a set of executable instructions. In some embodiments, the computer program code is configured to cause the cluster-type architecture 100 to be usable for performing a portion or all of the noted processes and/or methods in processing the wafers. In one or more embodiments, the hardware processor includes a central processing unit (CPU), a multi-processor, a distributed processing system, an application specific integrated circuit (ASIC), and/or a suitable processing unit. The control device 300 can be implemented by a computer or any suitable computation device.

As illustratively shown in FIG. 2, the cluster-type architecture 100 includes load lock chambers 12A and 12B, multiple chambers 18 and a central transfer chamber 20. In some embodiments, the chambers 18 includes process chamber(s) disposed around the central transfer chamber 20 equipped with a wafer transport system 22 for transporting the wafers among the load lock chambers 12A, 12B and the multiple chambers 18. The configurations of FIG. 2 are given for illustrative purposes. Various implements are within the contemplated scope of the present disclosure. For example, in some embodiments, the cluster-type architecture 100 includes more than two chambers 18.

In some embodiments, the wafer transport system 22 is implemented by a transfer robot.

In some embodiments, each of the load lock chambers 12A and the 12B is configured to receive a wafer carrier (cassette or holder) 40 holding multiple (semiconductor) wafers 41. In some embodiments, the chambers 18 include an orientation chamber and a cooldown chamber, and the load lock chambers 12A and 12B are flanked by the orientation chamber and the cooldown chamber, as shown in the embodiments of FIG. 2.

Process chambers in the chambers 18 for carrying out various processes in the fabrication of integrated circuits on the wafers 41 are positioned with the orientation chamber, the cooldown chamber, and the load lock chambers 12A and 12B around the central transfer chamber 20. The wafer transport system 22 in the central transfer chamber 20 is fitted with a transfer blade 24.

In some embodiments, the transfer blade 24 is implemented by vacuum arms that are configured to move the wafer 41 in the horizontal direction (e.g., on x-y plane). The transfer blade 24 is configured to receive and to support the individual wafers 41 from the wafer carrier 40 in each of the load lock chambers 12A and 12B. The wafer transport system 22 is capable of rotating the transfer blade 24 in the clockwise or counterclockwise direction in the central transfer chamber 20, and the transfer blade 24 can extend or retract to facilitate placement and removal of the wafers 41 in and from the load lock chambers 12A and 12B, the orientation chamber, the cooldown chamber and the process chambers 18.

According to some embodiments, in operation, for example, the load lock chamber 12A is controlled to move vertically (e.g., z direction) the wafer carrier 40 to set the selected wafer 41 in the wafer carrier 40 to an accessible level for the transfer blade 24 in the central transfer chamber 20. Then, the transfer blade 24 initially removes the wafer 41 from the wafer carrier 40 and then inserts the wafer 41 in the one of the chambers 18, for example, the orientation chamber. The wafer transport system 22 then transfers the wafer 41 from the orientation chamber to one or more of the process chambers, where the wafer 41 is subjected to a chemical vapor deposition or other process.

When the manufacturing process is complete, the wafer transport system 22 transfers the wafer 41 from the process chamber to the cooldown chamber, and ultimately, back to the wafer carrier 40 in the load lock chamber 12A. In some embodiments, after moving the wafer 41 out from the cooldown chamber, the wafer transport system 22 transfers the wafer 41 to the wafer carrier 40 in another load lock chamber 12B.

The cluster-type architecture 100 further includes various sensors (not shown in diagram), such like, flow sensor, current transformer, miniature photo sensor, reed switch, laser rangefinder, gauge pressure sensor, differential pressure transducer, density meter, temperature sensor, vibration meter, light intensity meter, and/or any suitable sensor configured to sense necessary values/parameters in the manufacturing processes.

The configurations of FIGS. 1-2 are given for illustrative purposes. Various implements are within the contemplated scope of the present disclosure. For example, in some embodiments, the manufacturing system 1 includes multiple cluster-type architectures 100 coupled to the module circuit 200 and the control device 300.

In some embodiments, the cluster-type architecture 100 is implemented by thermal processing system, deposition system, atomic layer deposition system, coater, plasma etch system, cleaning system, wafer prober, wafer bonder, wafer/dicing frame prober, and/or any process architecture performing semiconductor processes.

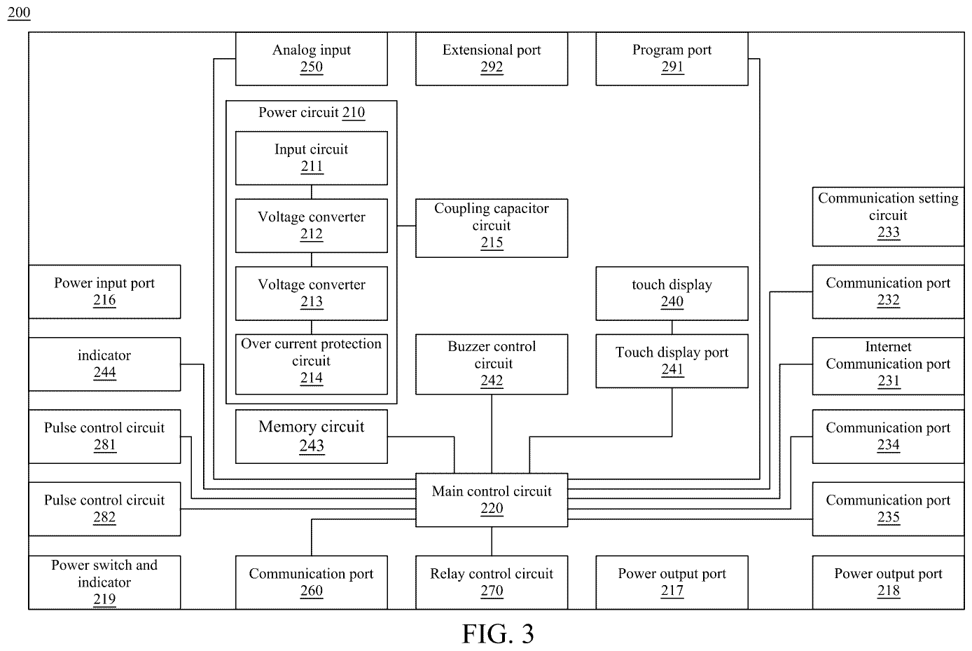

Reference is now made to FIG. 3. FIG. 3 is a schematic diagram of the module circuit corresponding to FIG. 2, in accordance with various embodiments of the present disclosure.

As shown in FIG. 3, the module circuit 200 includes a power circuit 210 configured to supply power, based on electrical power input through a power input port (e.g., a 9-36 Volts direct current power input plug), to circuits in the module circuit 200. In some embodiments, the power circuit also outputs supply voltage through power output ports 217-218 to supply other sensing devices that are configured to generate sensing signals/data to the module circuit 200 for further analysis. For example, the power output port 217 outputs a voltage (e.g., 24 Volts direct current power) provided by the power circuit 210. The power output port 218 outputs another voltage (e.g., 5 Volts direct current power) provided by the power circuit 210.

In some embodiments, the power circuit 210 further includes an input circuit 211, voltage converters 212-213, and an over current protection circuit 214. The input circuit 211 is coupled to the power input port 216 for receiving electrical power input (e.g., 24 Volts direct current voltage.) The voltage converter 212 is configured to convert the electrical power input to a first voltage (e.g., 5 Volts direct current power). The voltage converter 213 is coupled to the voltage converter 212 and configured to convert the first voltage to a second voltage different from the first voltage (e.g., 3.3 Volts direct current power). The over current protection circuit 214 is coupled to voltage converter 213 and configured as a protection circuit to prevent surge or over current from the voltage converter 213 and to output the second voltage to the inner other circuit components in the module circuit 200.

In some embodiments, the module circuit 200 further includes a coupling capacitor circuit 215 coupled between the power circuit 210 and a main control circuit 220 of the module circuit 200. The coupling capacitor circuit 215 is configured to decouple the second voltage with the module circuit 200 for filtering.

In some embodiments, the module circuit 200 further includes a power switch and indicator 219 which is coupled to the input circuit 211. The power switch and indicator 219 includes lighting devices, e.g., light emitting diodes to emit light in response to connection between the input circuit 211 and the power input port 216.

As illustratively shown in FIG. 3, the module circuit 200 further includes a main control circuit 220 and communication ports 231-232, 234-235 coupled to the main control circuit 220, a touch display 240, a touch display port 241 coupled between the touch display 240 and the main control circuit 220, a buzzer control circuit 242, a memory circuit 243, an analog input 250, a communication port 260, a relay control circuit 270, pulse control circuits 281-282, a program port 291, and an extensional port 292 that are coupled to the main control circuit 220. In some embodiments, the module circuit 200 is installed in an aluminum shell including front panel, back panel, left side panel, right side panel, upper cover, and base plate for better heat release.

In some embodiments, the module circuit 200 is coupled to the cluster-type architecture 100, the control device 300, and/or other semiconductor manufacturing tools (not shown) through various ports/communication circuits, such as the communication ports 231-232, 234-235, the analog input 250, the communication port 260, the relay control circuit 270, the pulse control circuits 281-282, the program port 291, and the extensional port 292.

During operations, according to some embodiments, the module circuit 200 is configured to receive sensing signals, sensing data, and/or control signals from the cluster-type architecture 100 and/or the control device 300 through the communication circuits in FIG. 3 in response to a mode select signal from the touch display. The module circuit 200 is further configured to operate at least one of: generating, based on at least one detection pattern, at least one control signal to the cluster-type architecture 100 to control at least one operation process; comparing sensing data from the cluster-type architecture 100 with at least one threshold data to generate a comparison result; generating, based on the comparison result, at least one other control signal to the cluster-type architecture 100; analyzing, according to at least one test pattern, at least one sensing signal from the process architecture to generate an analysis result; and transmitting or generating at least one control signal associated with analysis result to the cluster-type architecture 100 through the communication circuits mentioned above. In some embodiments, the at least one test pattern and the at least one detection pattern are programmed in the module circuit 200 by the control device 300 through the program port 291 or one of the communication ports 231, 235. In some embodiments, the cluster-type architecture 100 is configured to perform at least one process in response to the at least one other control signal.

In aforementioned embodiments, the sensing data and/or sensing signals refer to output data and/or signals from the sensors, such like, flow sensor, current transformer, miniature photo sensor, reed switch, laser rangefinder, gauge pressure sensor, differential pressure transducer, density meter, temperature sensor, vibration meter, light intensity meter, and/or any suitable sensor configured to sense necessary values/parameters in the manufacturing processes in the cluster-type architecture 100. The configurations of sensing data/or sensing signals are given for illustrative purposes. Various implements are within the contemplated scope of the present disclosure.

In some embodiments, for example, the touch display 240 can be a capacitive touch screen or any other suitable touch display device.

In some embodiments, the buzzer control circuit 242 is configured to generate alarm information, e.g., warning sounds, in response to the control signals from the main control circuit 220 to indicate comparison result and/or the analysis result.

In some embodiments, the main control circuit 220 saves the sensing data or data fetched based on the sensing signals in the memory circuit 243. In some embodiments, the main control circuit 220 accesses data stored in the memory circuit 243 for analysis.

In some embodiments, the indicator 244 is configured to illuminate in response to the control signals from the main control circuit 220 to indicate that signal transmissions take place between the module circuit 200 and devices coupled thereto.

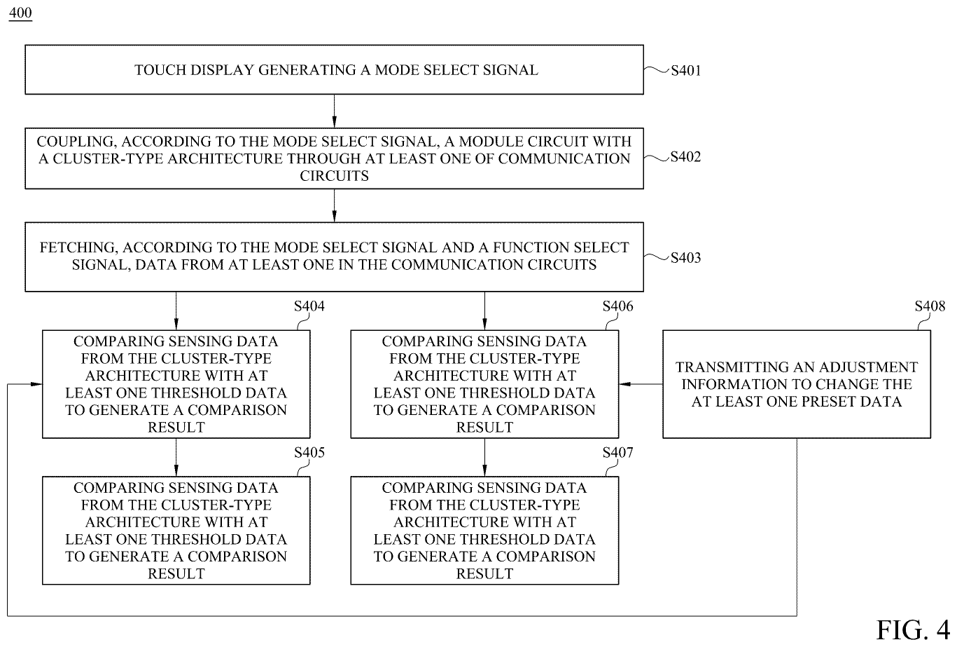

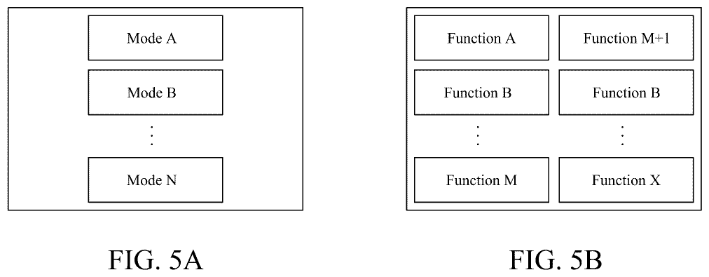

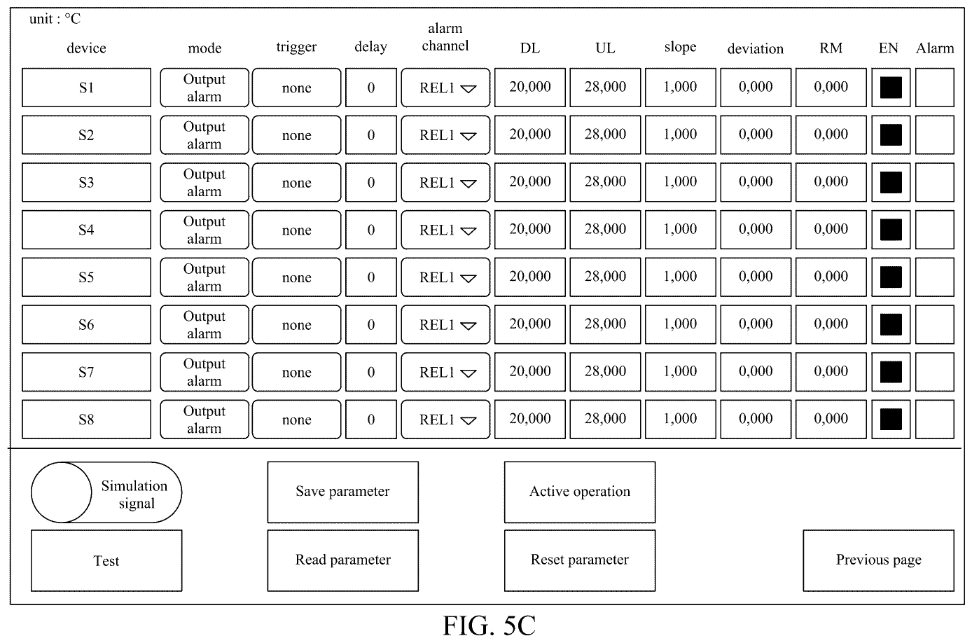

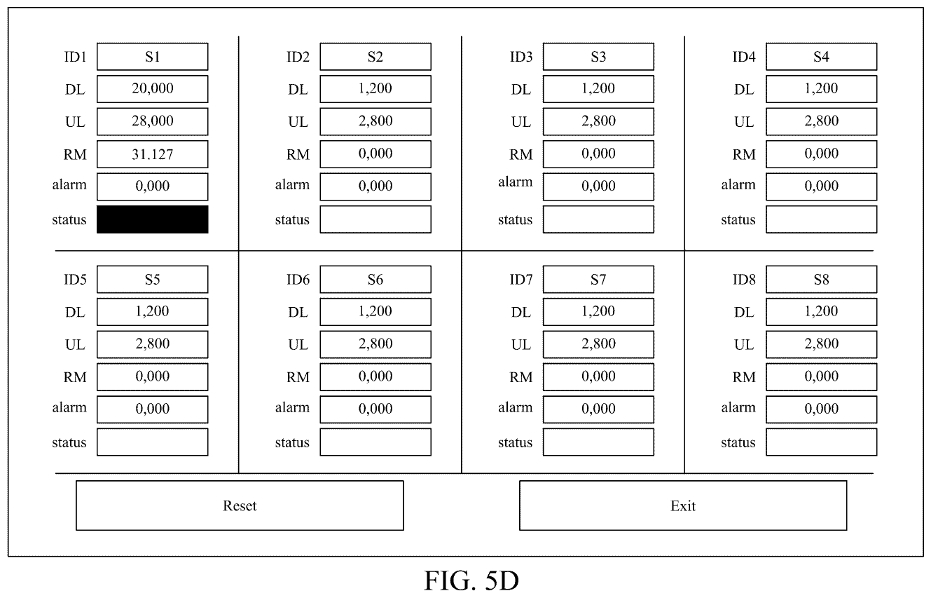

Reference is now made to FIG. 4. FIG. 4 is a flowchart diagram of a method 400 for operating the manufacturing system 1 corresponding to FIG. 1, in accordance with some embodiments of the present disclosure. It is understood that additional operations can be provided before, during, and after the processes shown by FIG. 4, and some of the operations described below can be replaced or eliminated, for additional embodiments of the method 400. The order of the operations/processes may be interchangeable. Throughout the various views and illustrative embodiments, like reference numbers are used to designate like elements. The method 400 includes operations S401-S408 that are described below with reference to the manufacturing system 1 and FIGS. 1-8, in which FIGS. 5A-8 show schematic diagrams of screen snaps corresponding to the touch display 240.

In operation S401, the touch display 240 generates, in response to a touch operation, a mode select signal to the main control circuit 220 through the touch display port 241. For example, as shown in FIG. 5A, the touch display 240 shows multiple bottoms each corresponding to one of several operation modes, e.g., Mode A to Mode N, of the module circuit 200. In some embodiments, the modes Mode A to Mode N includes engineering mode, basic test mode, instruction mode, customization mode . . . etc. After one of the bottoms is pressed during the touch operation, the touch display 240 generates the mode select signal indicating a selected mode from the listed modes in FIG. 5A.

In some embodiments, for engineering mode, basic test mode, instruction mode, customization mode, corresponding processes are programmed, for example, in C language or other suitable programming languages, into the main control circuit 220. For instance, in some embodiments, the engineering mode includes operations, as shown in operations S403-405, of fetching sensing data and/or sensing signals, based on a corresponding one in detection patterns, from a certain type of sensors in the cluster-type architecture 100, for example, temperature sensors, comparing sensing data with at least one preset data, e.g., threshold data to generate a comparison result, and generating, based on the comparison result, at least one control signal to the cluster-type architecture 100.

According to some embodiments, the method 400 further includes operations of displaying by the touch display 240, according to the comparison result, the sensing data, alarm information and the at least one threshold data that correspond to each of the plurality of sensors.

In some embodiments, the method 400 further includes operations of the touch display receiving adjustment information to change with at least one preset data, e.g., threshold data, and generating updated comparison result based on the changed preset data for further generating, based on the updated comparison result, at least one updated control signal to the cluster-type architecture 100, and/or displaying the updated comparison result on the touch display 240.

In various embodiments, the engineering mode further includes operations, as shown in operations S403, S406, S407, of fetching sensing data and/or sensing signals, based on a corresponding one in detection patterns, from sensors in the cluster-type architecture 100, analyzing, according to at least one test pattern stored in the module circuit 200, at least one sensing signal to generate an analysis result, and transmitting or generating at least one control signal associated with analysis result to the cluster-type architecture 100 through the communication circuits. In some embodiments, the test pattern includes preset data that are compared with the received sensing data for generating the analysis result. For example, in some embodiments, the main control circuit 220 generates, according to the at least one in the preset data and the received corresponding data from one of the communication circuits, the analysis result to the touch display 240 for visualized results on the touch display 240.

In some embodiments, the method 400 further includes operations of the control device 300 fetching the analysis result from the module circuit 200 and further generating, according to the analysis result, at least one control signal to the cluster-type architecture 100 through the module circuit 200. In some embodiments, the cluster-type architecture 100 performs at least one second process in response to the control signal from the control device 300.

In some embodiments, the method 400 includes operations of the control device 300 adjusting the test pattern in response to the analysis result. For example, when the analysis result indicates that longer interval time for integration operation to a sensing signal is required for better observation, the control device 300 adjusts the interval time preset in the test pattern.

In some embodiments, the method 400 includes operations of the touch display 240 transmitting the adjustment information to the main control circuit 220 to change at least one parameter in the preset data.

In some embodiments, the basic test mode and the customization mode include at least one operation featuring in the engineering mode. In some embodiments, the test pattern and/detection pattern in the customization mode are programmed or adjusted by the control device 300 through coupling the program port 291.

Reference is now made to FIGS. 5A-5D in which embodiments of method 400 are shown. As shown in FIG. 5A, a list of multiple modes Mode A to Mode N are provided on the touch display 240. For example, the mode Mode A corresponds to the engineering mode, the mode Mode B corresponds to the basic mode, the mode Mode C corresponds to the instruction mode that provides a manual for operating the manufacturing system 1 and/or the module circuit 200, and the mode Mode D corresponds to the customization mode.

For example, during the touch operation, a bottom corresponds to the mode Mode A is pressed, the touch display 240 generates the model select signal to the main control circuit 220, according to operation S401.

In operation S402, the main control circuit 220 is further coupled to the cluster-type architecture 100 in response to the model select signal through a corresponding communication circuit, for example, the analog input 250.

In FIG. 5B are several bottoms Function A to Function X correspond to different functions based on detection patterns and test patterns of the module circuit 200. In some embodiments, some function correspond to the detection patterns indicating, such like, operation configuration of the module circuit 200 to detect sense data from the laser rangefinder, the temperature sensors, the current meters, ultraviolet intensity sensors, gas/liquid flow sensors, pressure sensors, chiller system monitors, vibration meters, and/or any suitable sensor configured to sense necessary values/parameters in the manufacturing processes.

In various embodiments, some function of FIG. 5B correspond to the test patterns indicating, such like, analysis methodology/parameters for generating analysis result based on the sense data from the sensors or devices (e.g., mentioned with respect to the detection pattern) coupled to the module circuit 200.

For example, during the touch operation, a bottom corresponds to the function Function A is pressed, the touch display 240 generates the function select signal to the main control circuit 220, in which the function Function A corresponds to the detection pattern indicating fetching sense data from temperature sensors.

As shown in FIG. 5C, after a bottom corresponding to “active operation” is pressed, the touch display 240 transmits a control signal to the main control circuit 220 to trigger a data fetching operation. Consequently, sense data from all enabled (labeled as “EN”) temperature sensors S1-S8 in the cluster-type architecture 100 are transmitted to the module circuit 200 through the analog input 250 and shown in a real-time value column RM in table of the touch display 240. In some embodiments, the preset data in the detection pattern include upper limits UL (referred to as threshold data), bottom limits DL (referred to as threshold data), value gains (e.g., slope and deviation), control channels (e.g., corresponding ones, for example, relay REL1-REL4 in the relay control circuit 270), alarm mode, triggers and delay time.

In some embodiments, for example, the main control circuit 220 adjusts the real-time sense data according to the linear equation in slope-intercept form corresponding to the slope and deviation, and further compares the adjusted real-time sense data of each sensor with corresponding upper limits UL and bottom limits DL to generate corresponding comparison results shown in an alarm column in FIG. 5C or in a status row in FIG. 5D.

For example, as shown FIG. 5D, for the sensor S1, the adjusted real-time sense data RM is 31.127 that exceeds the upper limit 28.00. Accordingly, the block of the status is shown in dark in response to the comparison result to indicate alarm information that manufacturing situation corresponding to the sensor S1 is abnormal. In some embodiments, the main control circuit 220 generates control signals to the relay control circuit 270 to disable, by the interlock circuit coupled to the relay control circuit 270, an operation corresponding to the sensor S1 in the cluster-type architecture 100.

Furthermore, in the embodiments of FIGS. 5C-5D, several bottoms for controlling operations are provided. For example, the touch display 240 generates control signals to the main control circuit 220 in response to the touch operation in which the bottom is pressed. In FIG. 5C, a bottom “save parameter” corresponds to an operation of saving all the parameters in the current detection pattern into the main control circuit 220. A bottom “read parameter” corresponds to an operation of reading out saved parameters from the main control circuit 220 for the current detection operation. A bottom “reset parameter” corresponds to an operation of reset parameters to default values. A bottom “test” corresponds to test operations for the current detection operation, such like connection tests between the module circuit 200 and the sensors S1-S8. A bottom “simulation signal” corresponds to an operation of generating simulation signals for the current detection operation. A bottom “previous page” corresponds to an operation of returning to FIG. 5B for choosing other functions. In FIG. 5D, a bottom “reset” is configured with respect to, for example, “reset parameter” in FIG. 5C. A bottom “exit” is configured with respect to, for example, “previous page” in FIG. 5D.

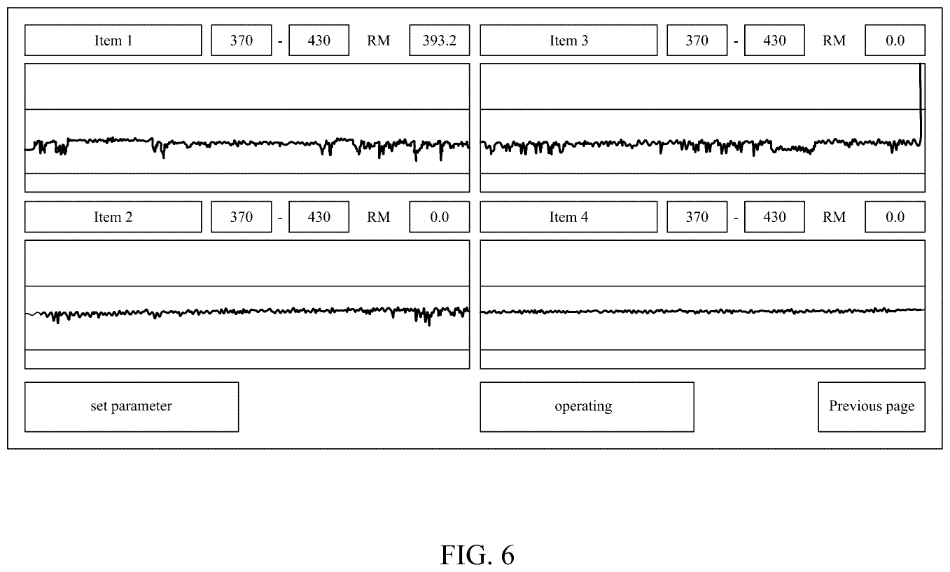

Reference is now made to FIG. 6. FIG. 6 shows a schematic diagram of a screen snap corresponding to the touch display 240 during operations, in accordance with various embodiments of the present disclosure.

As shown in the embodiments of FIG. 6 corresponding to the customization mode, analysis results associated with various sense data from different sensors and corresponding preset data indicating threshold ranges of sense data are shown in charts by the touch display 240. For example, the analysis result is generated based on test patterns including threshold ranges (e.g., 370-430) and recorded real-time values, and visualized the development of monitored sense data. In some embodiments, each of the item 1 to item 4 correspond to one gas pressure in manufacturing process, such like, photolithography clean dry air pressure, coating clean dry air pressure, chemical dinitrogen pressure, and photoresistor pressure.

Moreover, in FIG. 6, a bottom “set parameter” corresponds to an operation of further adjusting parameters that are used in the test pattern. For example, after pressing the “set parameter” bottom, the touch display 240 shows an input interface to receive new parameters and further transmits to the main control circuit 220 for adjusting the test pattern.

The configurations of FIG. 6 are given for illustrative purposes. Various implements are within the contemplated scope of the present disclosure. For example, in some embodiments, the control device 300 can transmit a control signal to the module circuit 200 to reselect sensor to fetch corresponding data for which the analysis operation is performed.

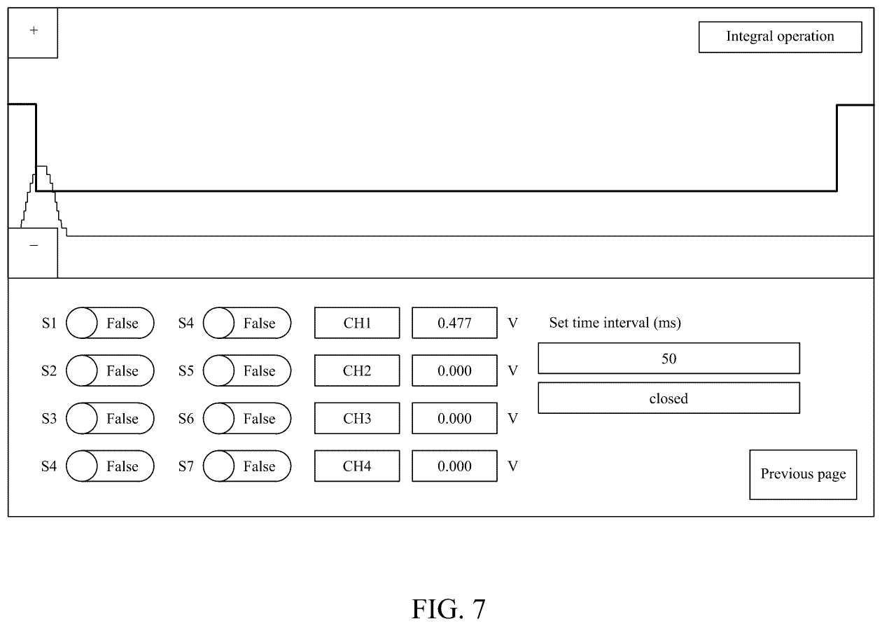

Reference is now made to FIG. 7. FIG. 7 shows a schematic diagram of a screen snap corresponding to the touch display 240 during operations, in accordance with various embodiments of the present disclosure.

As shown in FIG. 7 which illustrates an integral operation corresponding to a motor current in the cluster-type architecture 100, the main control circuit 220 receives sense data from selected current sensor and integrates the sense data as the analysis result with respect to the set time interval of the test pattern, e.g., 50 ms. The touch display 240 further displays the analysis result for monitor.

In some embodiments, the adjustment information, e.g., time interval different from the preset 50 ms, is received by the touch display 240 during the touch operation and transmitted to the main control circuit 220 to change the time interval data in the test pattern, and the main control circuit 220 further generates the updated analysis result based on the new time interval data. In some embodiments, the adjustment information includes sensor selection signals that indicate data of selected sensor(s) will be analyzed.

The configurations of FIG. 7 are given for illustrative purposes. Various implements are within the contemplated scope of the present disclosure. For example, in some embodiments, the test pattern includes algorithms that are different from the integration and are for customized analysis.

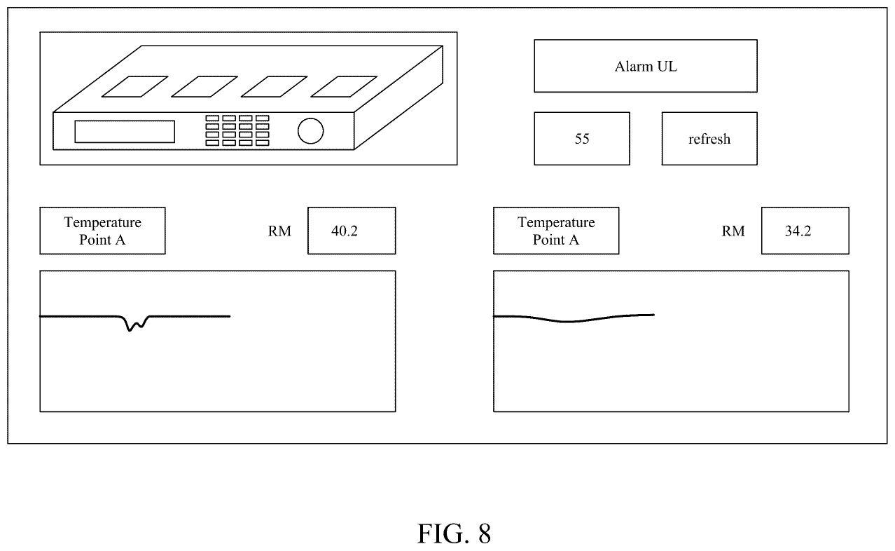

Reference is now made to FIG. 8. FIG. 8 shows a schematic diagram of a screen snap corresponding to the touch display 240 during operations, in accordance with various embodiments of the present disclosure.

As shown in FIG. 8, when the detection pattern indicates monitoring two temperature points A and B in the cluster-type architecture 100, the main control circuit 220 receives sense data from two temperature sensors and fan speed data of cooling fans at the temperature points A and B. In operation, the main control circuit 220 accordingly generates, based on the detection pattern, the comparison results including real-time temperature and fan speed data in charts that are displayed by the touch display 240.

In some embodiments, an alarm upper limit is preset in the detection pattern. When the real-time temperature at the temperature points A and/or B exceeds the alarm upper limit, the main control circuit 220 generates control signals to the controller 10 in the cluster-type architecture 100 for accelerating fan speed of corresponding fans or transmits the control signals to the pulse control circuits 281-282 for generating pulse-width modulation signals to control the fan speed of corresponding fans.

In some embodiments, the touch display 240 receives the adjustment information including an updated alarm upper limit and transmits corresponding control signals to the main control circuit 220 to change the preset data in the detection pattern. Accordingly, the main control circuit 220 generates the updated comparison results based on the updated alarm upper limit.

The configurations of FIG. 8 are given for illustrative purposes. Various implements are within the contemplated scope of the present disclosure. For example, in some embodiments, the control device 300 transmits the aforementioned adjustment information to the module circuit 200 to change the preset data in the detection pattern.

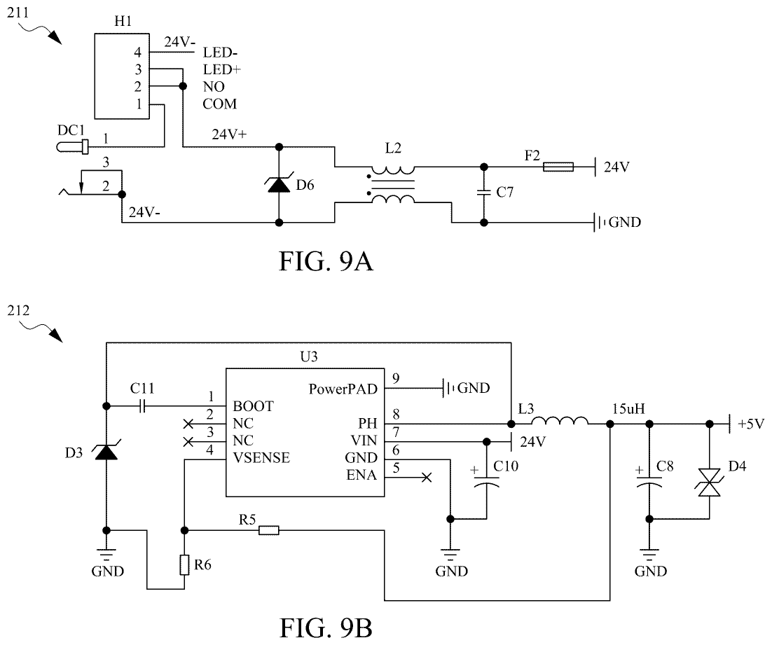

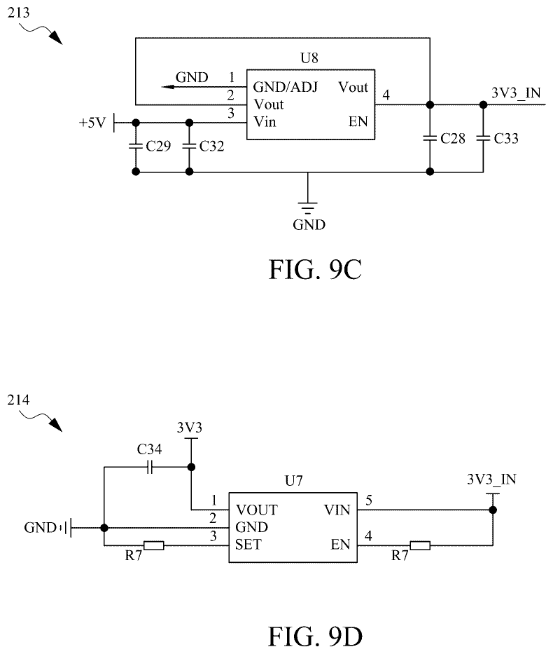

FIGS. 9A-22B depict embodiments corresponding to components in the module circuit 200. The configurations of FIGS. 9A-22B are given for illustrative purposes. Various implements are within the contemplated scope of the present disclosure. With respect to the embodiments of FIGS. 1-22B, like elements are designated with the same reference numbers for ease of understanding. The specific operations of similar elements and connection relationship, which are already discussed in detail in above paragraphs and/or depicts in figures, are omitted herein for the sake of brevity.

Reference is now made to FIGS. 9A-9D show schematic diagrams of components in a power circuit, in accordance with various embodiments of the present disclosure. FIG. 9A shows the input circuit 211 that includes a port DC1 coupled to the power input port 216, a port H1 coupled to the power switch and indicator 219, an inductor L2 coupled to a diode D6, a capacitor C7 and a fuse F2. The input circuit 211 generates a first voltage, for example, 24 Volts in response to power input from the power input port 216. In some embodiments, the port H1 is implemented by header-male 2.54.

FIG. 9B shows the voltage converter 212 is a DC-to-DC voltage converter and includes an integrated circuit U3 coupled to inductor L3, capacitors C10-C11, resistors R5-R6 and diode D4 in order to converter the first voltage from the input circuit 211 to a lower voltage, for example, +5V at an output terminal.

FIG. 9C shows the voltage converter 213 is a DC-to-DC voltage converter and includes an integrated circuit U8 coupled to capacitors C28-29, C32-C33, in order to converter the voltage (e.g., 5 Volts) from the voltage converter 212 to a lower voltage, for example, 3.3 Volts at an output terminal 3V3_IN.

FIG. 9D shows the over current protection circuit 214 that includes an integrated circuit U7 coupled to a capacitor C34 and resistors R3 and R7 in order to stabilize the voltage (e.g., 3.3 Volts) from the voltage converter 213 and output the voltage at an output terminal 3V3. In some embodiments, the integrated circuit U7 is implemented by a chip model of MT9700.

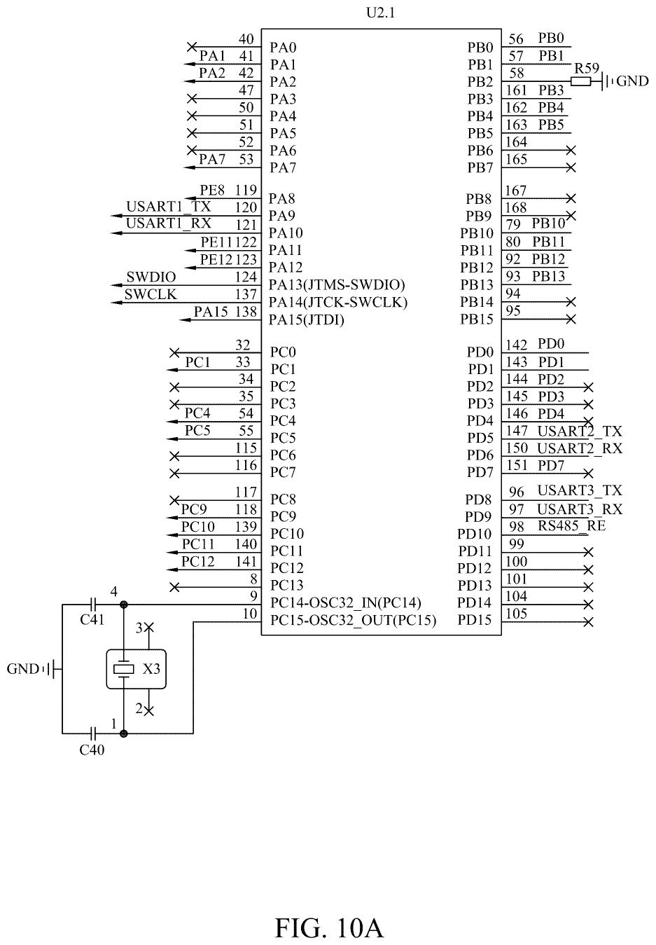

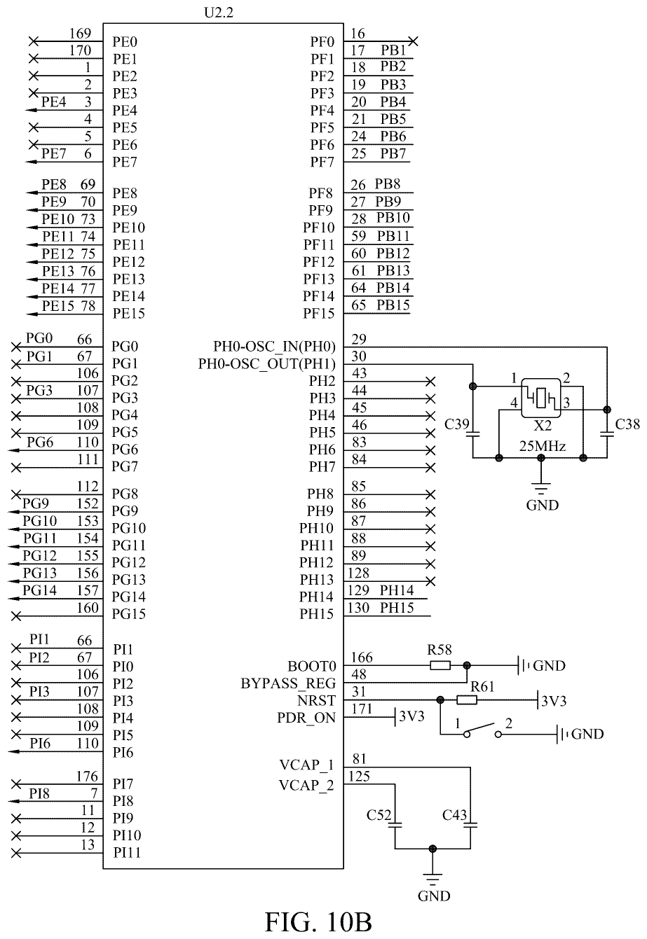

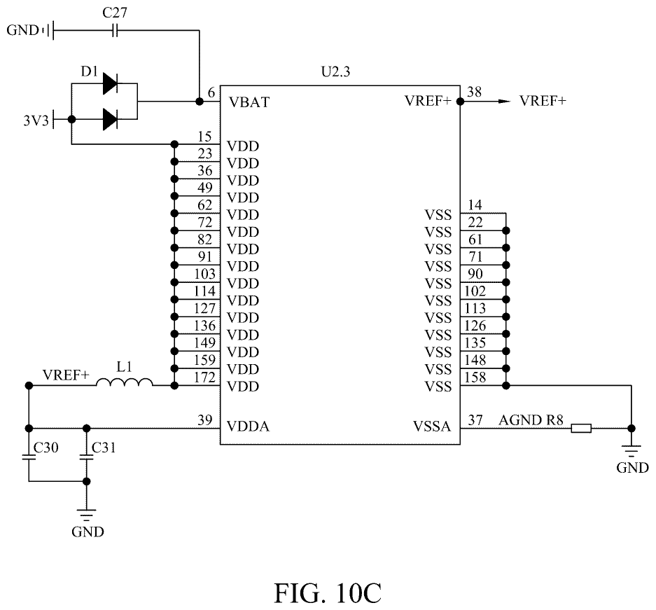

FIGS. 10A-10C show schematic diagrams of respective parts of the main control circuit 220, in accordance with various embodiments of the present disclosure. In some embodiments, the main control circuit 220 includes a chip shown in three portions U2.1 to U2.3 that is implemented by a chip model of STM32B407IGT6 and the corresponding configurations thereof are similar to the specifications of STM32B407IGT6. The detailed descriptions are omitted here.

As shown in FIG. 10A, the main control circuit 220 further includes a crystal oscillator X3 coupled to pins 9-10 of the portion U2.1 and capacitors C40-C41 and a resistor R59 coupled to pin 58. In FIG. 10B, the main control circuit 220 further includes a crystal oscillator X2 coupled to pins 29-30 of the portion U2.2 and capacitors C39-C38, a resistor R58 coupled to pins 48 and 166, a resistor R61 coupled to a switch coupled to a ground and further coupled between pin 31 and terminal 3V3, capacitors C43 and C52 that are coupled to pins 81 and 125 respectively. In some embodiments, the frequency (e.g., around 25 MHz) of the crystal oscillator X2, referred to as basic frequency of the system, is slower than that (e.g., around 32 MHz) of the crystal oscillator X3. In FIG. 10C, the main control circuit 220 further includes diodes D1 coupled to the terminal 3V3 and VDD inputs of the portion U2.3, capacitors C27, C30-C31, and a resistor R8 coupled between the ground and pin 37. In some embodiments, the resistance of the resistor R8 is zero ohms.

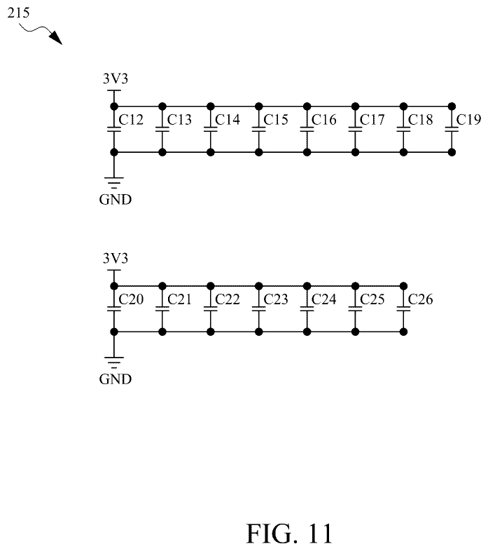

FIG. 11 is a schematic diagram of the coupling capacitor circuit 215, in accordance with various embodiments of the present disclosure. As shown in FGI .11, the coupling capacitor circuit 215 includes capacitors C12-C19 coupled in parallel between the ground and the terminal 3V3 and capacitors C20-C26 coupled in parallel between the ground and the terminal 3V3.

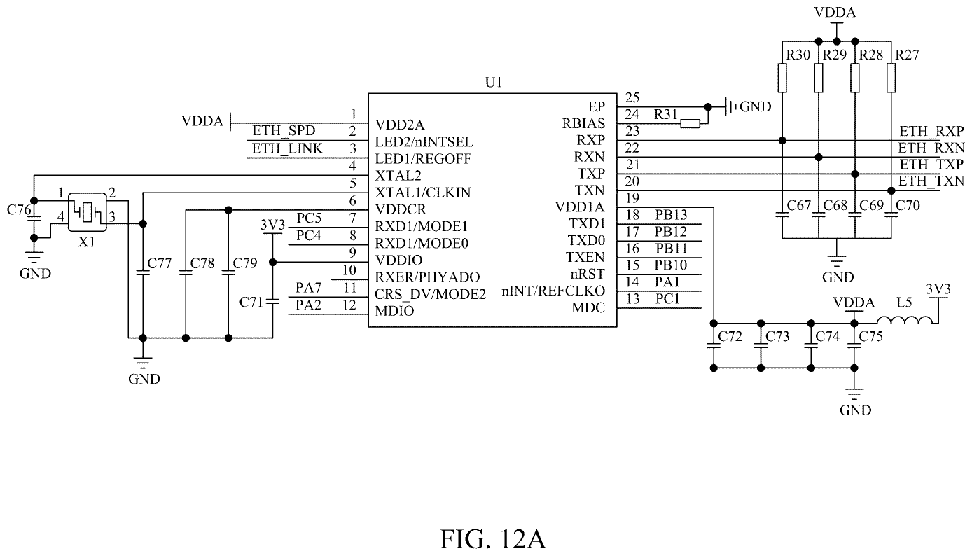

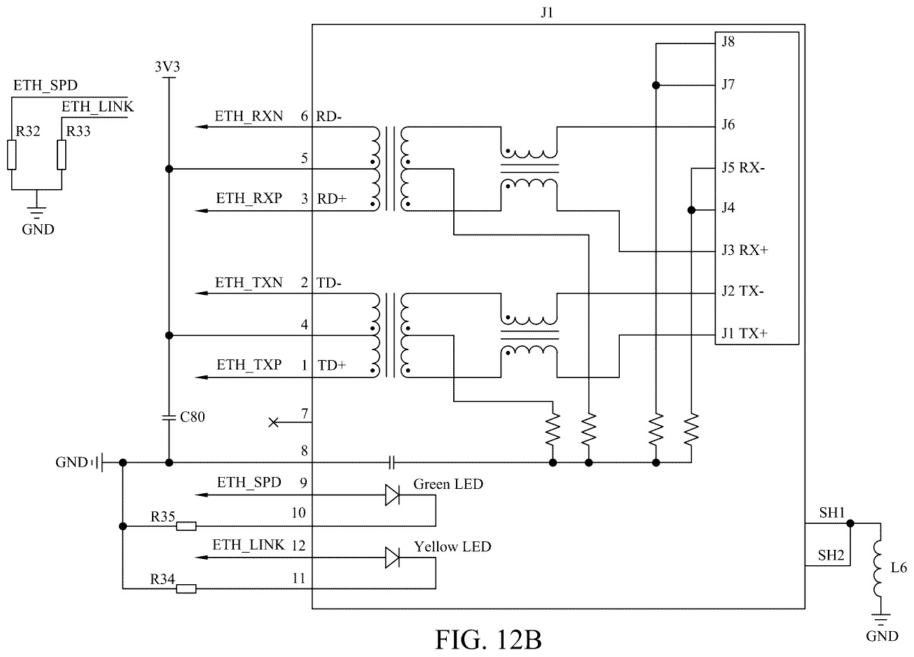

Reference is now made to FIGS. 12A-12B. FIGS. 12A-12B show schematic diagrams of components in the internet communication port 231, in accordance with various embodiments of the present disclosure. In FIG. 12A, the internet communication port 231 includes an integrated circuit U1 coupled to a crystal oscillator X1, capacitors C67-C75, an inductor L5, resistors R27-R31, and the main control circuit 220. In some embodiments, the integrated circuit U1 is implemented by a chip model of LAN8720A.

As shown in FIG. 12B, the internet communication port 231 further includes a network transformer J1 coupled to an inductor L6, resistors R32-R35, a capacitor C80, and the terminal 3V3. In some embodiments, the network transformer J1 is implemented by a model of HR91105A.

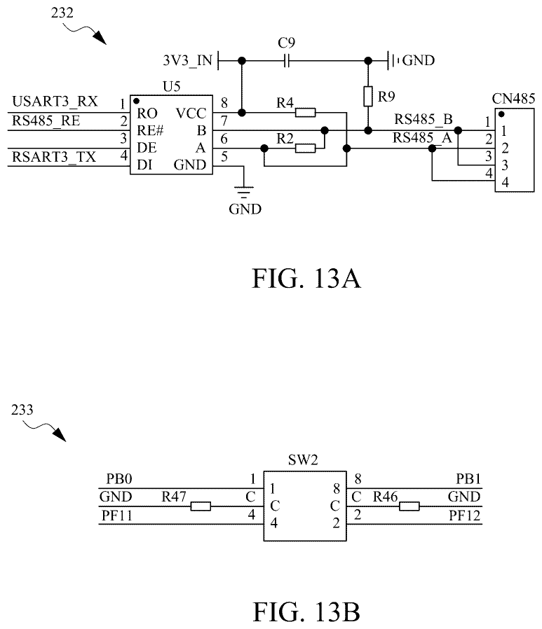

Reference is now made to FIGS. 13A-13B. FIGS. 13A-13B show schematic diagrams of the communication port 232 and the communication setting circuit 233 coupled thereto, in accordance with various embodiments of the present disclosure. In some embodiments, as shown in FIG. 13A, the communication port 232 is of physical layer protocol RS485 and coupled to a port CN485 and the main control circuit 220. The communication port 232 includes an integrated circuit U5 coupled to resistors R2, R4, R9, a capacitor C9, and the terminal 3V3_IN. In FIG. 13B, the communication setting circuit 233 is coupled to the main control circuit 220 and resistors R46-R47. In some embodiments, the communication setting circuit 233 is implemented by a chip model of TDR-16H for controlling the communication port 232.

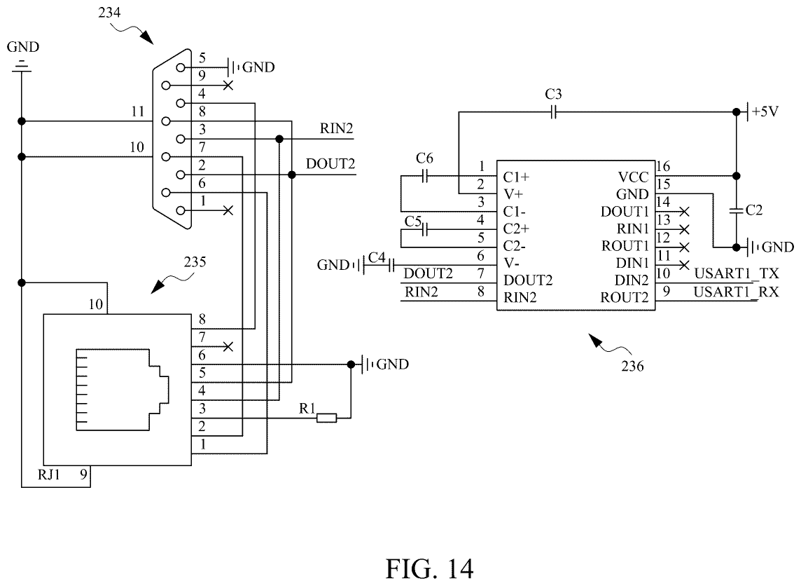

Reference is now made to FIG. 14. FIG. 14 is a schematic diagram of the communication port 234-235 and a converter 236 coupled thereto, in accordance with various embodiments of the present disclosure. As shown in FIG. 14, the communication port 234 is implemented as a Dsub connector and the communication port 235 is implemented as a RJ45 connector. The converter 236 is coupled between the main control circuit 220, the RJ45 connector and the Dsub connector, and configured to transmit the corresponding data from the RJ45 connector or the Dsub connector to the control circuit. In some embodiments, the main control circuit 220 is further configured to generate feedback data associated with the sensing data, and the converter 236 is further configured to transmit the feedback data from the control circuit to the RJ45 connector or the Dsub connector. In some embodiments, the Dsub connector is implemented by a port model DMR-9S, and the RJ45 connector is implemented by a port model R-RJ45R08P.

As shown in FIG. 14, a transmit plus pin (e.g., pin 1) of the RJ45 connector is coupled to a data-set-ready pin (e.g., pin 6) of the Dsub connector. A transmit minus pin (e.g., pin 2) of the RJ45 connector is coupled to a clear-to-send pin (e.g., pin 7) of the Dsub connector. A first not-connect pin (e.g., pin 5) of the RJ45 connector is coupled to a receive-data pin (e.g., pin 2) of the Dsub connector. A second not-connect pin (e.g., pin 4) of the RJ45 connector is coupled to a transmit-data pin (e.g., pin 3) of the Dsub connector. A third not-connect pin (e.g., pin 8) of the RJ45 connector is coupled to a data-terminal-ready pin (e.g., pin 4) of the Dsub connector. The transmit-data pin of the Dsub connector is coupled to a request-to-send pin of the Dsub connector. The receive-data pin of the Dsub connector is coupled to a read-in pin of the converter, and the transmit-data pin of the Dsub connector is coupled to a data-out pin of the converter 236.

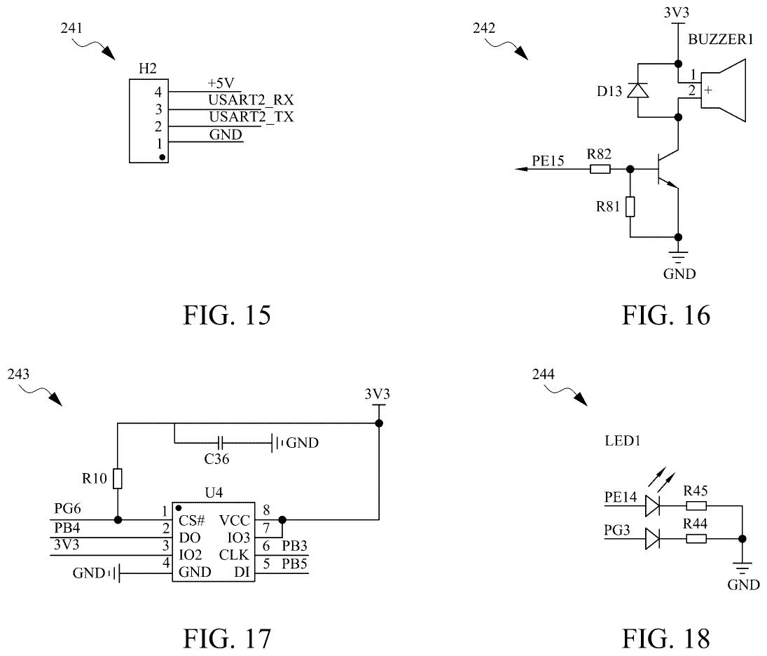

Reference is now made to FIG. 15. FIG. 15 is a schematic diagram of the touch display port 241, in accordance with various embodiments of the present disclosure. The touch display port 241 includes a port H2, implemented by header-male 2.54 in some embodiments.

Reference is now made to FIG. 16. FIG. 16 is a schematic diagram of the buzzer control circuit 242, in accordance with various embodiments of the present disclosure. The buzzer control circuit 242 includes a buzzer BUZZER1, implemented by a model HNB09A03 in some embodiments. The buzzer BUZZER1 is coupled to the main control circuit 220 through a diode D13, a transistor, and resistors R81-R82.

Reference is now made to FIG. 17. FIG. 17 is a schematic diagram of the memory circuit 243, in accordance with various embodiments of the present disclosure. The memory circuit 243 includes an integrated circuit U4, implemented by a model W25Q128JVSIQTR in some embodiments. The integrated circuit U4 is coupled to the main control circuit 220, the terminal 3V3, a resistors R10, and a capacitor C36.

Reference is node made to FIG. 18. FIG. 18 is a schematic diagram of the indicator 244, in accordance with various embodiments of the present disclosure. in some embodiments, the indicator 244 is coupled to the main control circuit 220 and resistors R44-45. In some embodiments, the indicator 244 is implemented by a model of A694B/2SUR/S530.

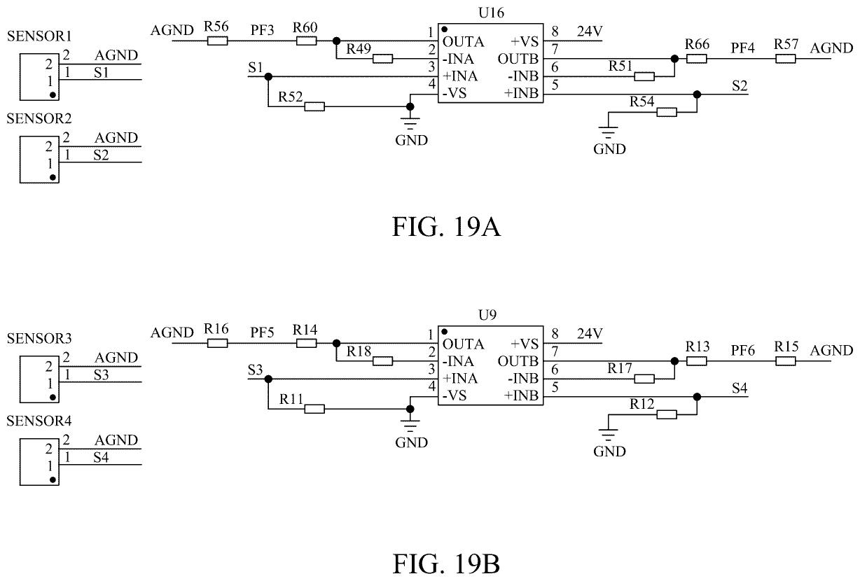

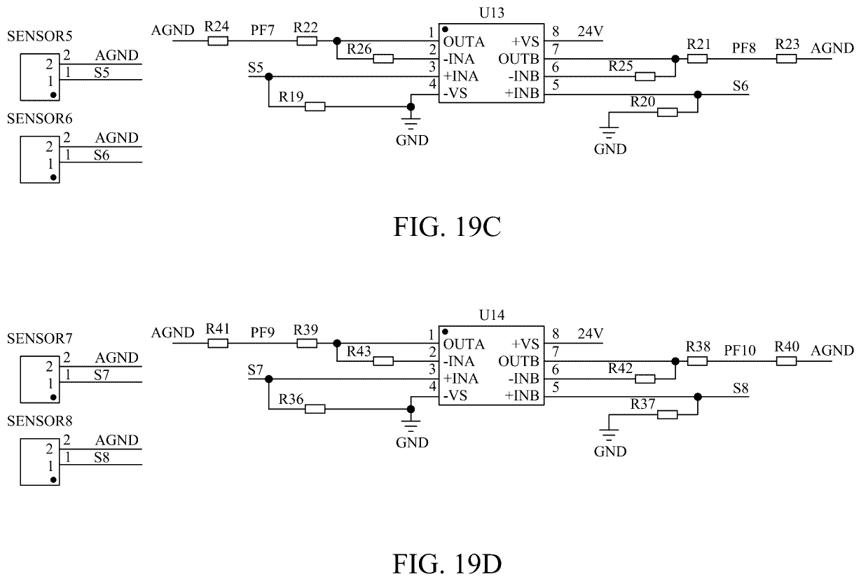

Reference is now made to FIGS. 19A-19D. FIGS. 19A-19D are schematic diagrams of the analog input 250, in accordance with various embodiments of the present disclosure. The analog input 250 includes integrated circuits U16, U9, U13, and U14, in which each one is coupled to corresponding two sensor ports in sensors SENSOR1-SENSOR8, as shown in FIGS. 19A-19D. The sensor ports are coupled to the cluster-type architecture 100. The integrated circuits U16, U9, U13, and U14 is configured to transmit received sensing signal/data to the main control circuit 220. In some embodiments, the analog input 250 is configured as a voltage follower.

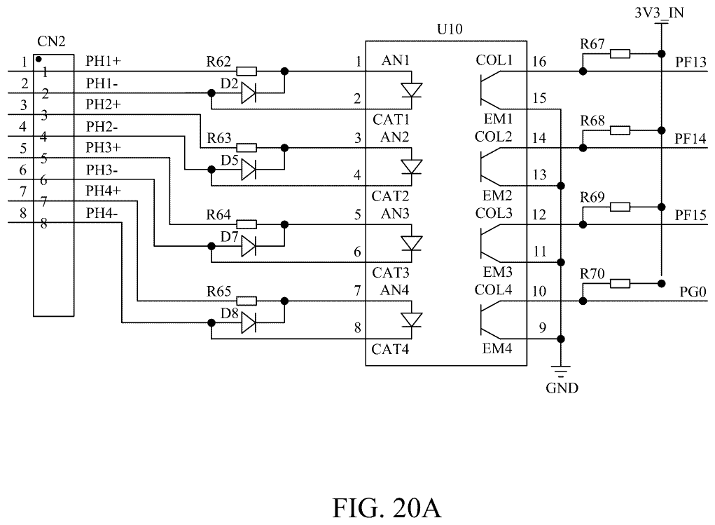

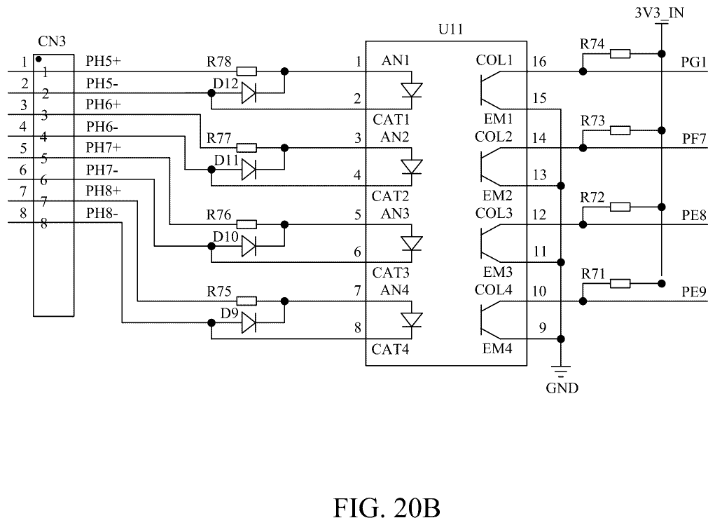

Reference is now made to FIGS. 20A-20B. FIGS. 20A-20B show schematic diagrams of components in the communication port 260, in accordance with various embodiments of the present disclosure. in some embodiments, the communication port 260 is an optocoupler that is coupled to the sensors and configured to generate, according to the portion of the sensing data, data signal to the main control circuit 220. In some embodiments, the communication port 260 includes integrated circuits U10-U11 that are implemented by a model LTV-247 in some embodiments, coupled to port CN2-CN3 implemented by a model KF2EDGR-3.81.

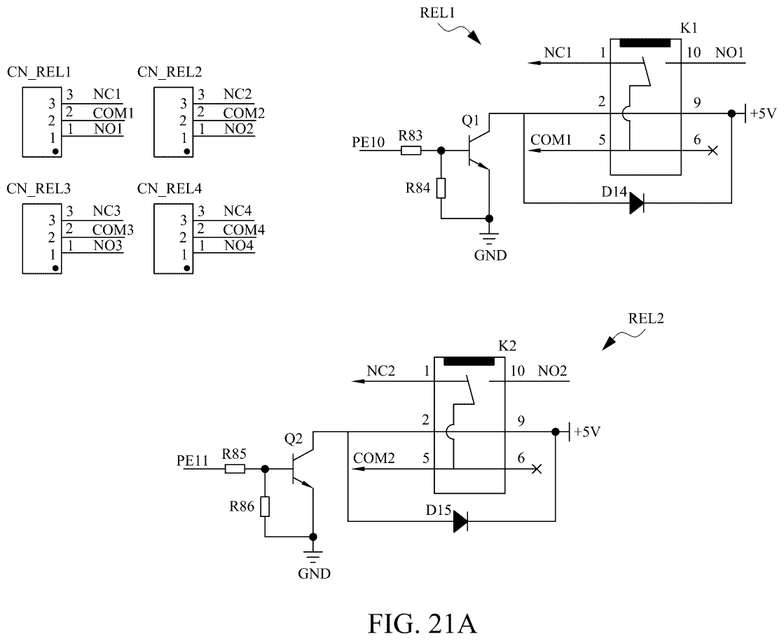

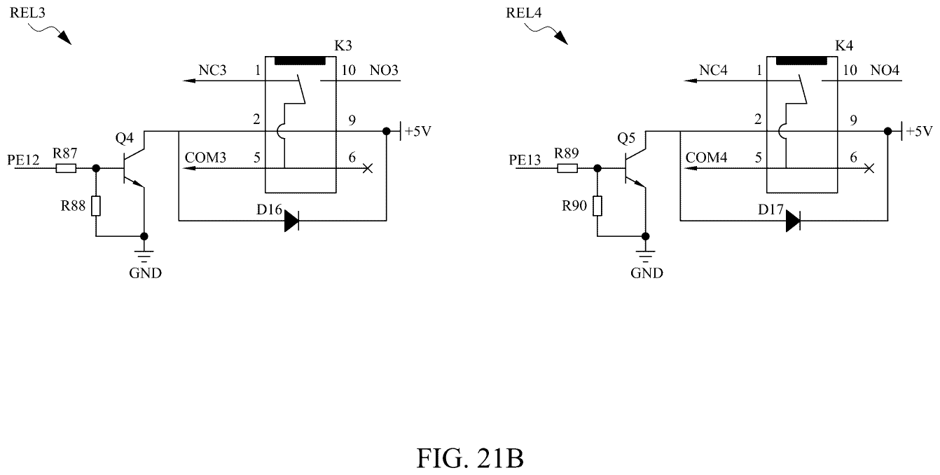

Reference is now made to FIGS. 21A-21B. FIGS. 21A-21B show schematic diagrams of components in a relay control circuit 270, in accordance with various embodiments of the present disclosure. The relay control circuit 270 is coupled to the main control circuit 220 and the interlock circuit 500 through relay circuit REL1-REL4. In some embodiments, the relay control circuits 270 configured to selectively disconnect the interlock circuit 500 in response to the control signals from the main control circuit 220. Each of the relay circuit is configured to generate a relay signal as one of the control signals in response to the control signals from the main control circuit 220 to a corresponding port in ports CN_REL1-CN_REL4.

As shown in FIGS. 21A-21B, each of the relay circuits REL1-REL4 includes a first resistor (e.g., one of R83, R85, R87, R89) having a first terminal coupled to the control circuit 220; a transistor (e.g., one of Q1, Q2, Q4, Q5) having a gate terminal coupled to a second terminal of the first resistor, a first terminal coupled to a relay coil, and a second terminal coupled to the ground; and a second resistor (e.g., one of R84, R86, R88, R90) coupled between the gate terminal of the transistor and the ground.

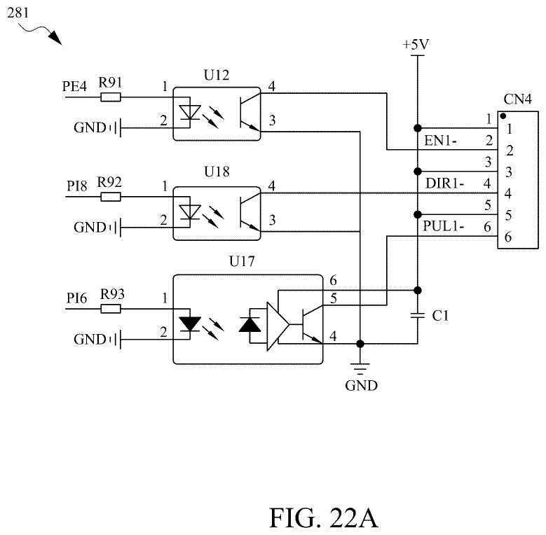

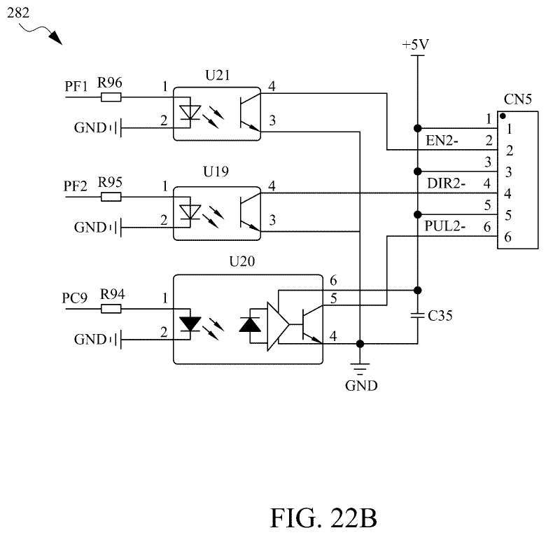

Reference is now made to FIGS. 22A-22B. FIGS. 22A-22B show schematic diagrams of components in pulse control circuits 281-282, in accordance with various embodiments of the present disclosure. In some embodiments, the pulse control circuit 281 and/or 282 generates a pulse-width modulation signal as the control signal in response to control signals corresponding to the comparison result. For example, when the sensing data corresponds to temperature data of the cluster-type architecture 100 and the temperature data is out of range of the at least one threshold data, the pulse control circuit 281 generates the at least one second control signal to accelerate a speed of a cooling device in the cluster-type architecture 100. In some embodiments, for controlling different devices in the cluster-type architecture 100, the pulse control circuits 281-282 generate different pulse-width modulation signals.

As shown in FIGS. 22A-22B, the pulse control circuits 281-282 includes integrated circuits U12, U18, U21, U19 (e.g., implemented by a model EL357N(B)(TA)) respectively, integrated circuits U17, U20 (e.g., implemented by a model TLP2362) respectively, and ports CN4-CN5 (e.g., implemented by a model KF2EDGR).

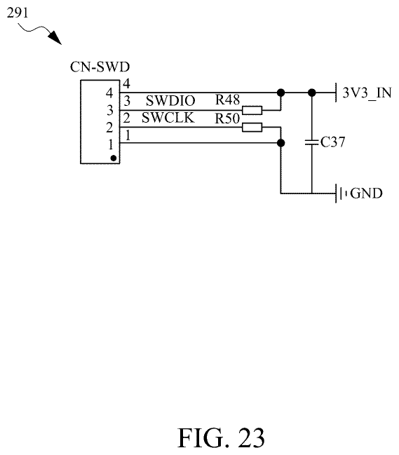

Reference is now made to FIG. 23. FIG. 23 is a schematic diagram of the program port 291, in accordance with various embodiments of the present disclosure. The program port 291 includes a port CW-SWD and coupled to the main control circuit 220, a capacitor C37, resistors R48, R50, and the terminal 3V3_IN. in some embodiments, the control device 300 is coupled to the module circuit 200 through the program port 291.

As described above, a manufacturing system and a method are provided. The module circuit is designed for sensor data networking and automating equipment, allowing engineers to handle simple project development and automation tasks without needing to program or design circuits. It includes a flexible data collection interface compatible with a wide range of sensors, a capacitive touch screen, and pre-programmed functions tailored to manufacturing needs. The module's built-in acquisition programs, data transformation formulas, and communication protocols ensure efficient sensor data integration and machine automation.

In some embodiments, the system includes a process architecture; and a module circuit coupled to the process architecture through a plurality of ports and configured to operate at least one of: generating, based on at least one detection pattern, at least one first control signal to the process architecture to control at least one operation process; comparing sensing data from the process architecture with at least one threshold data to generate a comparison result; and generating, based on the comparison result, at least one second control signal to the process architecture, wherein the process architecture is configured to perform at least one first process in response to the at least one second control signal.

In some embodiments, the module circuit is further configured to analyzing, according to at least one test pattern stored in the module circuit, at least one sensing signal from the process architecture to generate an analysis result. The system further comprises a control device configured to fetch the analysis result from the module circuit and further configured to generate, according to the analysis result, at least one third control signal to the process architecture through the module circuit. The process architecture is configured to perform at least one second process in response to the at least one third control signal.

In some embodiments, the control device is further configured to adjust the at least one test pattern in response to the analysis result.

In some embodiments, the system further comprises an interlock circuit coupled between the module circuit and the process architecture. The module circuit comprises a control circuit configured to generate a plurality of third control signals according to the comparison result; and a plurality of relay circuits configured to selectively disconnect the interlock circuit in response to the plurality of third control signals.

In some embodiments, each of the plurality of relay circuits comprises: a first resistor having a first terminal coupled to the control circuit; a transistor having a gate terminal coupled to a second terminal of the first resistor, a first terminal coupled to a relay coil, and a second terminal coupled to a ground; and a second resistor coupled between the gate terminal of the transistor and the ground.

In some embodiments, the process architecture comprises a plurality of sensors each generating portion of the sensing data. The module circuit comprises: a touch display configured to display, according to the comparison result, the sensing data, alarm information and the at least one threshold data that correspond to each of the plurality of sensors.

In some embodiments, the touch display is further configured to receive an adjustment information to change the at least one threshold data.

In some embodiments, the module circuit further comprises a pulse control circuit configured to generate a pulse-width modulation signal as the at least one second control signal in response to a plurality of third control signals corresponding to the comparison result. When the sensing data corresponds to temperature data of the process architecture and the temperature data is out of range of the at least one threshold data, the pulse control circuit generates the at least one second control signal to accelerate a speed of a cooling device in the process architecture.

In some embodiments, the process architecture comprises a plurality of sensors each generating portion of the sensing data. The module circuit further comprises an optocoupler coupled to the plurality of sensors and configured to generate, according to the portion of the sensing data, a plurality of data signals; and a control circuit configured to generate, according to the data signals, the plurality of third control signals to the pulse control circuit.

In some embodiments, a module circuit for a semiconductor process architecture, comprises: a touch display configured to generate a mode select signal and a function select signal; a plurality of first communication circuits each configured to receive corresponding data; a control circuit configured to fetch, according to the mode select signal and the function select signal, data from at least one in the plurality of communication circuits and configured to generate, according to a plurality of preset data, a plurality of first control signals; and a plurality of second communication circuits configured to generate, according to the plurality of first control signals, a plurality of second control signals different from the plurality of first control signals.

In some embodiments, the plurality of first communication circuits comprises: a RJ45 connector; a Dsub connector coupled to the RJ45 connector; and a converter coupled between the control circuit, the RJ45 connector and the Dsub connector, and configured to transmit the corresponding data from the RJ45 connector or the Dsub connector to the control circuit. The control circuit is further configured to generate feedback data associated with the corresponding data. The converter is further configured to transmit the feedback data from the control circuit to the RJ45 connector or the Dsub connector.

In some embodiments, a transmit plus pin of the RJ45 connector is coupled to a data-set-ready pin of the Dsub connector, a transmit minus pin of the RJ45 connector is coupled to a clear-to-send pin of the Dsub connector, a first not-connect pin of the RJ45 connector is coupled to a receive-data pin of the Dsub connector, a second not-connect pin of the RJ45 connector is coupled to a transmit-data pin of the Dsub connector, a third not-connect pin of the RJ45 connector is coupled to a data-terminal-ready pin of the Dsub connector, and the transmit-data pin of the Dsub connector is coupled to a request-to-send pin of the Dsub connector.

In some embodiments, the receive-data pin of the Dsub connector is coupled to a read-in pin of the converter, and the transmit-data pin of the Dsub connector is coupled to a data-out pin of the converter.

In some embodiments, the touch display is further configured to transmit an adjustment information to the control circuit to change at least one in the preset data. The control circuit is further configured to generate, according to the at least one in the preset data and the received corresponding data from one of the communication circuits, an analysis result to the touch display. The touch display is further configured to display the analysis result.

In some embodiments, the plurality of second communication circuits comprise: a plurality of relay circuits coupled to the control circuit, wherein each of the plurality of relay circuit is configured to generate a relay signal as one of the plurality of second control signals in response to the plurality of first control signals.

In some embodiments, the plurality of second communication circuits further comprise: a first pulse control circuit configured to generate a first pulse-width modulation signal as one of the plurality of second control signals in response to a first portion of the plurality of first control signals; and a second pulse control circuit configured to generate a second pulse-width modulation signal as one of the plurality of second control signals in response to in response to a second portion, different from the first portion, of the plurality of first control signals.

In some embodiments, A method comprises: coupling, according to a mode select signal, a module circuit with a process architecture through at least one in a plurality of communication circuits; generating, by the module circuit, an analysis result according to at least one test pattern stored in the module circuit and at least one sensing signal from the at least one in the plurality of first communication circuits; controlling, by at least one first control signal, a controller in the process architecture to perform at least one process by the process architecture, wherein the at least one first control signal that is generated by the module circuit according to the analysis result and transmitted through at least one in the plurality of communication circuits; and monitoring the at least one process, by the module circuit, the at least one sensing signal to adjust the at least one control signal.

In some embodiments, the method further comprises: fetching, by a control device, the analysis result from the module circuit; and transmitting, by the module circuit, a second control signal to control the controller, wherein the second control signal is generated by the control device according to the analysis result.

In some embodiments, the method further comprises: initiating a customized process of the process architecture in response to a third control signal from the control device.

In some embodiments, the method further comprises: enabling, by an interlock circuit, an initial operation of a transfer blade in the process architecture in response to at least one second control signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a process architecture; and
a module circuit coupled to the process architecture through a plurality of ports and configured to operate at least one of:
generating, based on at least one detection pattern, at least one first control signal to the process architecture to control at least one operation process;
comparing sensing data from the process architecture with at least one threshold data to generate a comparison result; and
generating, based on the comparison result, at least one second control signal to the process architecture, wherein the process architecture is configured to perform at least one first process in response to the at least one second control signal.

2. The system of claim 1, wherein the module circuit is further configured to analyzing, according to at least one test pattern stored in the module circuit, at least one sensing signal from the process architecture to generate an analysis result,
wherein the system further comprises:
a control device configured to fetch the analysis result from the module circuit and further configured to generate, according to the analysis result, at least one third control signal to the process architecture through the module circuit,
wherein the process architecture is configured to perform at least one second process in response to the at least one third control signal.

3. The system of claim 2, wherein the control device is further configured to adjust the at least one test pattern in response to the analysis result.

4. The system of claim 1, further comprising:
an interlock circuit coupled between the module circuit and the process architecture,
wherein the module circuit comprises:
a control circuit configured to generate a plurality of third control signals according to the comparison result; and
a plurality of relay circuits configured to selectively disconnect the interlock circuit in response to the plurality of third control signals.

5. The system of claim 4, wherein each of the plurality of relay circuits comprises:
a first resistor having a first terminal coupled to the control circuit;
a transistor having a gate terminal coupled to a second terminal of the first resistor, a first terminal coupled to a relay coil, and a second terminal coupled to a ground; and
a second resistor coupled between the gate terminal of the transistor and the ground.

6. The system of claim 1, wherein the process architecture comprises a plurality of sensors each generating portion of the sensing data;
wherein the module circuit comprises:
a touch display configured to display, according to the comparison result, the sensing data, alarm information and the at least one threshold data that correspond to each of the plurality of sensors.

7. The system of claim 6, wherein the touch display is further configured to receive an adjustment information to change the at least one threshold data.

8. The system of claim 1, wherein the module circuit further comprises:
a pulse control circuit configured to generate a pulse-width modulation signal as the at least one second control signal in response to a plurality of third control signals corresponding to the comparison result,
wherein when the sensing data corresponds to temperature data of the process architecture and the temperature data is out of range of the at least one threshold data,
the pulse control circuit generates the at least one second control signal to accelerate a speed of a cooling device in the process architecture.

9. The system of claim 8, wherein the process architecture comprises a plurality of sensors each generating portion of the sensing data;
wherein the module circuit further comprises:
an optocoupler coupled to the plurality of sensors and configured to generate, according to the portion of the sensing data, a plurality of data signals; and
a control circuit configured to generate, according to the data signals, the plurality of third control signals to the pulse control circuit.

10. A module circuit for a semiconductor process architecture, comprising:
a touch display configured to generate a mode select signal and a function select signal;
a plurality of first communication circuits each configured to receive corresponding data;
a control circuit configured to fetch, according to the mode select signal and the function select signal, data from at least one in the plurality of first communication circuits and configured to generate, according to a plurality of preset data, a plurality of first control signals; and
a plurality of second communication circuits configured to generate, according to the plurality of first control signals, a plurality of second control signals different from the plurality of first control signals.

11. The module circuit of claim 10, wherein the plurality of first communication circuits comprises:
a RJ45 connector;
a Dsub connector coupled to the RJ45 connector; and
a converter coupled between the control circuit, the RJ45 connector and the Dsub connector, and configured to transmit the corresponding data from the RJ45 connector or the Dsub connector to the control circuit,
wherein the control circuit is further configured to generate feedback data associated with the corresponding data,
wherein the converter is further configured to transmit the feedback data from the control circuit to the RJ45 connector or the Dsub connector.

12. The module circuit of claim 11, wherein
a transmit plus pin of the RJ45 connector is coupled to a data-set-ready pin of the Dsub connector,
a transmit minus pin of the RJ45 connector is coupled to a clear-to-send pin of the Dsub connector,
a first not-connect pin of the RJ45 connector is coupled to a receive-data pin of the Dsub connector,
a second not-connect pin of the RJ45 connector is coupled to a transmit-data pin of the Dsub connector,
a third not-connect pin of the RJ45 connector is coupled to a data-terminal-ready pin of the Dsub connector, and
the transmit-data pin of the Dsub connector is coupled to a request-to-send pin of the Dsub connector.

13. The module circuit of claim 12, wherein the receive-data pin of the Dsub connector is coupled to a read-in pin of the converter, and
the transmit-data pin of the Dsub connector is coupled to a data-out pin of the converter.

14. The module circuit of claim 10, wherein the touch display is further configured to transmit an adjustment information to the control circuit to change at least one in the preset data,
wherein the control circuit is further configured to generate, according to the at least one in the preset data and the received corresponding data from one of the first communication circuits, an analysis result to the touch display,
wherein the touch display is further configured to display the analysis result.

15. The module circuit of claim 10, wherein the plurality of second communication circuits comprise:
a plurality of relay circuits coupled to the control circuit, wherein each of the plurality of relay circuit is configured to generate a relay signal as one of the plurality of second control signals in response to the plurality of first control signals.

16. The module circuit of claim 15, wherein the plurality of second communication circuits further comprise:
a first pulse control circuit configured to generate a first pulse-width modulation signal as one of the plurality of second control signals in response to in response to a first portion of the plurality of first control signals; and
a second pulse control circuit configured to generate a second pulse-width modulation signal as one of the plurality of second control signals in response to a second portion, different from the first portion, of the plurality of first control signals.

17. A method, comprising:
coupling, according to a mode select signal, a module circuit with a process architecture through at least one in a plurality of communication circuits;
generating, by the module circuit, an analysis result according to at least one test pattern stored in the module circuit and at least one sensing signal from the at least one in the plurality of communication circuits;
controlling, by at least one first control signal, a controller in the process architecture to perform at least one process by the process architecture, wherein the at least one first control signal that is generated by the module circuit according to the analysis result and transmitted through at least one in the plurality of communication circuits; and
monitoring the at least one process, by the module circuit, the at least one sensing signal to adjust the at least one control signal.

18. The method of claim 17, further comprising:
fetching, by a control device, the analysis result from the module circuit; and
transmitting, by the module circuit, a second control signal to control the controller, wherein the second control signal is generated by the control device according to the analysis result.

19. The method of claim 18, further comprising:
initiating a customized process of the process architecture in response to a third control signal from the control device.

20. The method of claim 17, further comprising:
enabling, by an interlock circuit, an initial operation of a transfer blade in the process architecture in response to at least one second control signal.
